(19) United States
(12) Patent Application Publication
(10) Pub. No.: US 2025/0112215 A1
(43) Pub. Date: Apr. 3, 2025

(54) DISPLAY PANEL AND DISPLAY DEVICE

(71) Applicant: Shanghai Tianma Micro-electronics Co., Ltd., Shanghai (CN)

(72) Inventors: Qijun YAO, Shanghai (CN); Quanpeng YU, Shanghai (CN)

(21) Appl. No.: 18/600,811

(22) Filed: Mar. 11, 2024

(30) Foreign Application Priority Data
Sep. 28, 2023 (CN) 202311280283.5

(51) Int. Cl. H01L 25/16; H01L 23/00

(52) U.S. Cl. CPC H01L 25/167; H01L 24/32; H01L 2224/32145; H01L 2924/12041; H01L 2924/1426

(57) ABSTRACT

A display panel includes an array substrate with a plurality of electrode pads formed on it. At least one electrode pad comprises a first area, a second area, and a third area. The third area connects the first area and the second area, and the first area of at least one electrode pad is equipped with a light-emitting element. A width of the third area is smaller than a width of the first area and a width of the second area, and/or a melting point of the third area is lower than a melting point of the first area or a melting point of the second area. This display panel can save a significant amount of space, facilitating the integration of functional structures and addressing the technical issue of low efficiency of space utilization in the display panel.

### CROSS-REFERENCE TO RELATED APPLICATION

This application claims priority to Chinese Patent Application No. 202311280283.5, filed on Sep. 28, 2023, the entire content of which is incorporated herein by reference.

### TECHNICAL FIELD

The present disclosure relates to the field of display technology and, in particular, to a display panel and a display device.

### BACKGROUND

As an important part of a display device, a display panel is used to realize a display function of the display device. A light-emitting structure of a light-emitting diode (LED) display panel mainly includes an electrode and a LED chip, having advantages including a low power consumption, high saturation extent, and a quick response. The light-emitting structure of an LED display panel has been widely used in many scenarios.

During a manufacturing process of a LED display panel, it is difficult to avoid LED chip failures. Therefore, a backup electrode pad is reserved to reposition an LED chip for repairing the LED display panel. Every LED chip must be equipped with a primary electrode pad and a backup electrode pad. The backup electrode pad occupies a large amount of space, causing a technical issue of low efficiency of space utilization of the LED display panel.

### SUMMARY

One aspect of the present disclosure provides a display panel. The display panel includes an array substrate and a plurality of electrode pads formed over the array substrate. At least one electrode pad of the plurality of electrode pads includes a first area, a second area, and a third area. The third area connects to each of the first area and the second area. A light-emitting element is configured over the first area of the at least one electrode pad of the plurality of electrode pads. A width of the third area is less than each of a width of the first area and a width of the second area; and/or a melting point of the third area is lower than a melting point of the first area or a melting point of the second area.

Another aspect of the present disclosure provides a display device. The display device includes a display panel. The display panel includes an array substrate and a plurality of electrode pads formed over the array substrate. At least one electrode pad of the plurality of electrode pads includes a first area, a second area, and a third area. The third area connects to each of the first area and the second area. A light-emitting element is configured over the first area of the at least one electrode pad of the plurality of electrode pads. A width of the third area is less than each of a width of the first area and a width of the second area; and/or a melting point of the third area is lower than a melting point of the first area or a melting point of the second

### BRIEF DESCRIPTION OF THE DRAWINGS

The accompanying drawings, which are incorporated in and constitute a part of this specification, illustrate embodiments of the present disclosure and together with the description, serve to explain the principles of the present disclosure.

In order to better illustrate embodiments of the present disclosure, the following will briefly introduce the drawings needed to describe embodiments of the present disclosure. Obviously, for those persons of ordinary skill in the art, additional drawings can be obtained based on illustrated drawings without exerting creative labor.

FIG. 1 illustrates a schematic cross-sectional view of a display panel according to various embodiments of the present disclosure.

FIG. 2 illustrates a schematic plan view of a display panel according to various embodiments of the present disclosure.

FIG. 3 illustrates a schematic diagram of a repairing process of the display panel according to various embodiments of the present disclosure.

FIG. 4 illustrates another schematic cross-sectional view of a display panel according to various embodiments of the present disclosure.

FIG. 5 illustrates another schematic plan view of a display panel according to various embodiments of the present disclosure.

FIG. 6 illustrates another schematic cross-sectional view of a display panel according to various embodiments of the present disclosure.

FIG. 7 illustrates another schematic cross-sectional view of a display panel according to various embodiments of the present disclosure.

FIG. 8 illustrates another schematic cross-sectional view of a display panel according to various embodiments of the present disclosure.

FIG. 9 illustrates another schematic cross-sectional view of a display panel according to various embodiments of the present disclosure.

FIG. 10 illustrates another schematic cross-sectional view of a display panel according to various embodiments of the present disclosure.

FIG. 11 illustrates another schematic plan view of a display panel according to various embodiments of the present disclosure.

FIG. 12 illustrates another schematic plan view of a display panel according to various embodiments of the present disclosure.

FIG. 13 illustrates another schematic cross-sectional view of a display panel according to various embodiments of the present disclosure.

FIG. 14 illustrates another schematic plan view of a display panel according to various embodiments of the present disclosure.

FIG. 15 illustrates another schematic plan view of a display panel according to various embodiments of the present disclosure.

FIG. 16 illustrates another schematic cross-sectional view of a display panel according to various embodiments of the present disclosure.

FIG. 17 illustrates another schematic plan view of a display panel according to various embodiments of the present disclosure.

### DETAILED DESCRIPTION OF THE EMBODIMENTS

In order to better understand objects, features, and advantages of the present disclosure, the present disclosure will be further described below. It should be noted that, as long as there is no conflict, embodiments of the present disclosure and features in the embodiments can be combined with each other.

Specific details are set forth in the following description to fully understand the present disclosure, but the present disclosure can also be implemented in ways different from those described here. Obviously, embodiments in the description are only part of embodiments of the present disclosure, rather than entire examples.

During the manufacturing process of a LED display panel, it is difficult to avoid a LED chip failure. Therefore, a backup electrode pad needs to be reserved to reposition a LED chip for repairing a display panel. Every LED chip must be equipped with a primary electrode pad and a backup electrode pad. The backup electrode pad occupies a large amount of space, causing a technical issue of low efficiency of space utilization of the display panel.

Embodiments of the present disclosure propose a display panel and a display device, which can save a large amount of space, facilitate the integration of other functional structures, and address a technical issue of low efficiency of space utilization of the display panel.

The display panel and the display device provided by embodiments of the present disclosure are exemplarily described below with reference to the accompanying drawings.

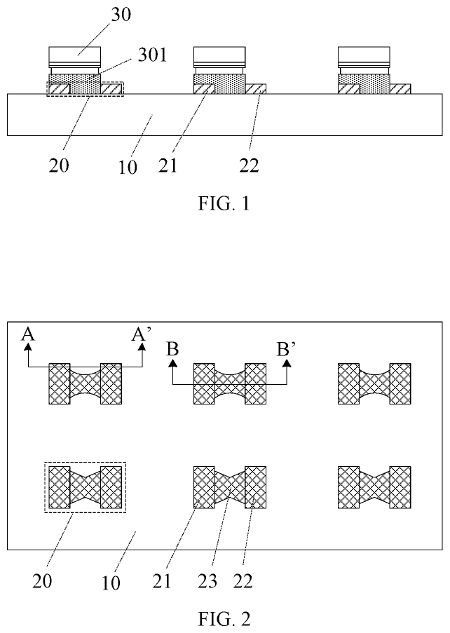

As shown in FIG. 1 and FIG. 2, FIG. 1 is a schematic cross-sectional view of a display panel provided by embodiments of the present disclosure. FIG. 2 is a schematic plan view of a display panel provided by embodiments of the present disclosure. FIG. 1 is a cross-sectional view along the cross-section line A-A′ in FIG. 2. The display panel includes an array substrate 10 on which a plurality of electrode pads 20 are formed.

Optionally, the array substrate 10 includes a driving module, and the driving module includes a circuit.

Specifically, the driving module includes a thin film transistor, which is electrically connected to an electrode pad of the plurality of electrode pads 20. A driving signal output from the thin film transistor is transmitted to a light-emitting element 30 through the electrode pad 20. Thus, the light-emitting element 30 emits light of corresponding brightness in gray scale.

At least one electrode pad 20 includes a first area 21, a second area 22, and a third area 23. The third area 23 connects the first area 21 and the second area 22. The first area 21 of the at least one electrode pad 20 is arranged with the light-emitting element 30. At least one second area 22 does not overlap with the light-emitting element 30.

It should be noted that in some embodiments, for a same electrode pad 20, the first area 21 is provided with the light-emitting element 30, and the second area 22 does not overlap with the light-emitting element 30. A eutectic layer 301 of the light-emitting element 30 is bonded to the first area 21 of the electrode pad 20. The eutectic layer 301 of the light-emitting element 30 does not overlap with the second area 22.

A width of the third area 23 is smaller than a width of the first area 21 and a width of the second area 22. A melting point of the third area 23 is lower than a melting point of the first area 21 or a melting point of the second area 22, facilitating disconnecting an electrical connection between the first area 21 and the second area 22.

If the light-emitting element 30 provided in the first area 21 fails, the electrical connection between the first area 21 and the second area 22 can be disconnected, and the light-emitting element 30 can be repositioned in the second area 22 to repair the display panel without arranging additional backup electrode pads 20, which saves a lot of space, facilitates the integration of other functional structures, and solves the technical issue of low efficiency of space utilization of the display panel.

Optionally, the light-emitting element 30 is a vertical structured Micro-LED. Micro-LED (Micro Light Emitting Diode) is a miniature light-emitting diode. A size of a single LED chip reaches an order of 10 microns. A cathode and an anode of the vertical structured Micro-LED are placed on the top and bottom of the LED chip respectively. The anode at the bottom of the LED chip is bonded to the electrode pad. The cathode on the top of the LED chip will be connected to a common electrode in the subsequent packaging process of the display panel.

By configuring the light-emitting element as the vertical structured Micro-LED and combining it with the electrode pad design in embodiments of the present disclosure, space occupied by a pad can be further simplified as well as the repairing process.

In some embodiments, as shown in FIG. 2, the width of the third area 23 is smaller than a width of the first area 21 and a width of the second area 22. Along a direction from the first area 21 to the second area 22, the width of the third area 23 decreases first and then increases, which means a width of a middle section of the third area 23 is the smallest. This facilitates the third area 23 to be disconnected from the middle.

It should be noted that a width mentioned here refers to the width of the first area 21, the width of the second area 22, and the width of the third area 23 along a direction perpendicular to the direction from the first area to the second area.

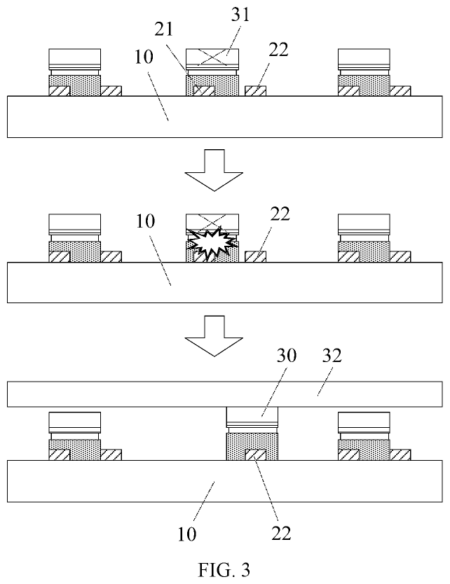

FIG. 3 shows a schematic diagram of the repairing process of the display panel provided by embodiments of the present disclosure. The light-emitting element located in the middle of FIG.3 is a defective light-emitting element 31 that is faulty and needs to be repaired. The defective light-emitting element 31 is first removed from the array substrate 10. The electrode pad 20 may be attached to the defective light-emitting element 31 and be removed together. As the width of the third area 23 of the electrode pad 20 is the smallest, it provides a disconnection path for separating the first area 21 from the second area 22. The electrode pad 20 will be directly disconnected at the third area 23. Therefore, only the first area 21 attached to the defective light-emitting element 31 is removed together, while the second area 22 remains on the array substrate 10. Then, the light-emitting element 30 is repositioned using an adapter board 32, and the repositioned light-emitting element 30 is bonded to the second area 22. In order to prevent the adapter board 32 from colliding with other light-emitting components that do not need to be repaired, a certain distance needs to be maintained between the adapter board 32 and other light-emitting components. Therefore, the light-emitting element 30 will be repositioned higher than the other light-emitting components.

Optionally, as shown in FIG. 2, an edge of the third area 23 is a concave arc shape or a concave polyline shape. The third area 23 of an upper three electrode pads 20 in FIG. 2 is a concave arc shape. The third area 23 of a lower three electrode pads 20 in FIG. 2 is a concave polygonal shape. Whether it is a concave arc shape or a concave polygonal shape, a concave side of a concave edge faces outside the third area 23 and the opposite convex side faces inside the third area 23. The electrode pad 20 is shaped like a dumbbell or an hourglass as a whole, making the third area 23 to be easily disconnected from the middle.

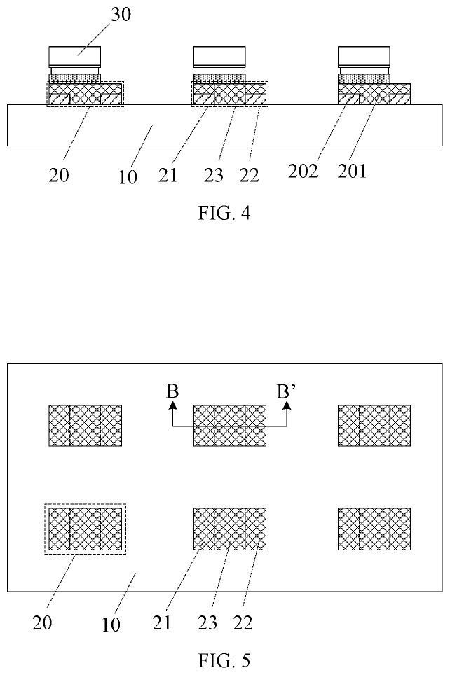

FIG. 4 is another schematic cross-sectional view of the display panel according to

embodiments of the present disclosure, and FIG. 5 is another schematic plan view of the display panel according to embodiments of the present disclosure. FIG. 4 is a schematic cross-sectional view along the cross-sectional line B-B′ in FIG. 5. The width of the first area 21 is same as the width of the second area 22 and the width of the third area 23. The third area 23 includes a first metal 201. The first area 21 and the second area 22 include a second metal 202 (which may also include the first metal 201). A melting point of the first metal 201 is lower than a melting point of the second metal 202. A melting point of the third area 23 is lower than a melting point of the first area 21 and a melting point of the second area 22, so that the third area 23 is easily cut off.

In some embodiments, a melting point of the first metal 201 is below 300° C., thus metals such as indium and tin can be used. A melting point of the second metal 202 is above 500° C., thus metals such as tungsten and molybdenum can be used. When repairing the display panel, ultraviolet light can be irradiated from a lower surface of the array substrate 10 to heat the electrode pad 20 to above the melting point of the first metal 201 but below the melting point of the second metal 202. Therefore, the first metal 201 becomes liquid, that is, it reaches a temperature at which the light-emitting element and the array substrate can be disconnected, and a temperature that is sufficient to cause the first area 21 and the second area 22 to be preferentially disconnected. The defective light-emitting elements in the first area 21 is removed. The electrical connection between the first area 21 and the second area 22 is disconnected. Then the light-emitting elements in the second area 22 is repositioned. After the first metal 201 of the second area 22 is cooled to a solid state, bonding of the repositioned light-emitting element and the electrode pad 20 is completed.

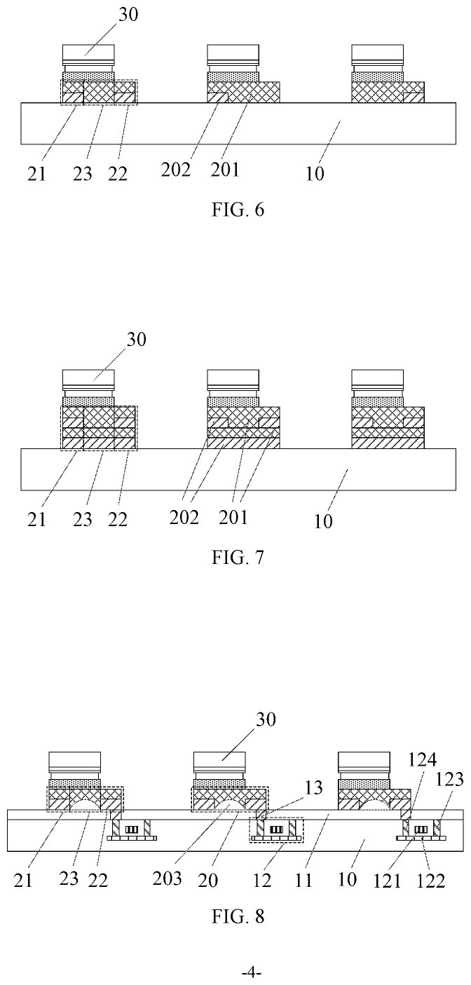

In some embodiments, as shown in the electrode pad 20 on the left side in FIG. 6, both the first area 21 and the second area 22 include a second metal 202. In some embodiments, as shown in the electrode pad 20 in the middle of FIG. 6, only the first area 21 includes the second metal 202. In some embodiments, as shown in the electrode pad 20 on the right side in FIG. 6, only the second area 22 includes the second metal 202.

FIG. 7 is another schematic cross-sectional view of a display panel according to embodiments of the present disclosure. The first area 21 and the second area 22 include n layers of metal, and the third area 23 includes m layers of metal, where m<n. For example, the first area 21 and the second area 22 include four layers of metal, which are specifically composed of two layers of the first metal 201 and two layers of the second metal 202 that are alternately laminated. The third area 23 includes three layers of metal, which are specifically composed of one layer of the second metal 202 and two layers of the first metal 201. Arranging the electrode pad 20 into an alternating stacked structure of metals with different melting points can improve the fault tolerance rate of bonding between the light-emitting element and the electrode pad 20, and is beneficial to improving the bonding yield of the light-emitting element.

In some embodiments, the width of the third area 23 may be smaller than the width of the first area 21 and the width of the second area 22. At the same time, the melting point of the third area 23 is also lower than the melting point of the first area 21 or the melting point of the second area 22. That is, FIG. 4 can also be a schematic cross-sectional view along the section line B-B′ in FIG. 2.

FIG. 8 is another schematic cross-sectional view of a display panel according to embodiments of the present disclosure. A spacer layer 203 is arranged between the third area 23 and the array substrate 10, which is equivalent to adding the spacer layer 203 at the bottom of the third area 23. This can save quantity of metal used in the third area 23 to some extents. More importantly, a thickness of the third area 23 is reduced, making the third area 23 easier to be disconnect. Therefore, the electrical connection between the first area 21 and the second area 22 is disconnected.

Optionally, the spacer layer 203 is made of an insulating material and does not interfere with conduction performance of the electrode pad 20. The spacer layer 203 can be made of organic materials, such as polyimide, or inorganic materials, such as silicon oxide, silicon nitride, etc.

In some embodiments, along the direction from the first area 21 to the second area 22, a thickness of the spacer layer 203 first increases and then decreases, that is, a thickness of the middle section of the third area 23 is the smallest, which facilitates the third area 23 from being disconnected in the middle. When repairing the display panel, the third area 23 can be cut off by means of laser, ultraviolet light, etc. A defective light-emitting element in the first area 21 can be removed, and the light-emitting element can be repositioned in the second area 22.

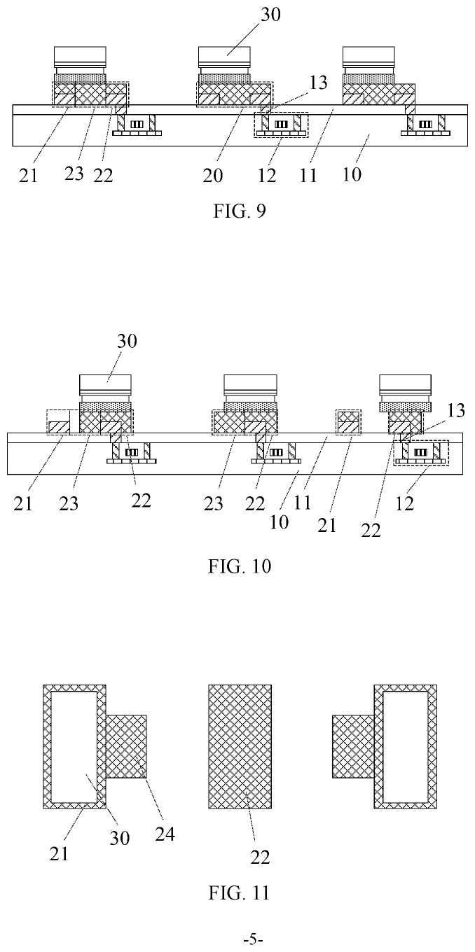

In some embodiments, as shown in FIGS. 8, 9, and 10, the array substrate 10 further includes a driving component and at least a first insulating layer 11 located between the driving component and the electrode pad 20. There is a first via hole 13 in the first insulating layer 11. The electrode pad 20 is electrically connected to the driving component through the first via hole 13, and the second area 22 of the electrode pad 20 overlaps the first via hole 13. The driving component may include a thin film transistor 12 and a metal trace (not shown in the figure) connected to the thin film transistor 12. The thin film transistor 12 includes a gate electrode 121, a semiconductor 122, a source electrode 123, and a drain electrode 124. The electrode pad 20 is connected to the drain electrode 124 of the thin film transistor 12 through the first via hole 13. A driving signal output from the drain electrode 124 of the thin film transistor 12 can be transmitted to the light-emitting element 30 through the electrode pad 20, making the light-emitting element 30 emit corresponding brightness in gray scale. After the display panel is repaired, the electrical connection between the first area 21 and the second area 22 is disconnected, and the light-emitting element 30 repositioned in the second area 22 can still receive the driving signal output by the thin film transistor 12.

In some embodiments, a plurality of insulating layers may be included between the driving component and the electrode pad. The first via hole also penetrates the plurality of insulating layers to achieve electrical connection between the electrode pad and the driving component.

In some embodiments, the array substrate 10 includes a thin film transistor (TFT for short) 12, and the third area 23 does not overlap with the thin film transistor 12. The array substrate 10 includes a forbidden area of the thin film transistor 12. The forbidden area means that the thin film transistor 12 is not disposed in the forbidden area. The forbidden area overlaps with the third area 23. When repairing the display panel, ultraviolet light is irradiated from the lower surface of the array substrate 10, especially the third area 23, to heat up the electrode pad. Therefore, a structure of the third area 23 not overlapping with the thin film transistor 12 can prevent ultraviolet light damaging a structure and performance of the thin film transistor 12 as well as prevent the thin film transistor 12 blocking ultraviolet light.

FIG. 10 is another schematic cross-sectional view of a display panel according to embodiments of the present disclosure, and is a shape of the repaired electrode pad and the light-emitting element 30. The light-emitting element 30 is disposed on the second area 22 of at least one electrode pad in the display panel, and the electrical connection between the first area 21 and the second area 22 has been disconnected.

Due to a structural difference in the electrode pads of display panels of different models, as well as differences in the intensity and exposure time of ultraviolet light during the repairing process of the display panel, the repaired electrode pads will display different shapes.

As shown in the electrode pad on the left side in FIG. 10, the second area 22 on which the electrode pad of the light-emitting element 30 is disposed is disconnected from the first area 21. When repairing the display panel, the first metal 201 is heated to a liquid state and a defective light-emitting element in the first area 21 is removed. In this process, the first metal 201 in the first area 21 and part of the first metal 201 in the third area 23 that are attached to the defective light-emitting element are also removed. The second metal 202 in the first area 21 remains on the array substrate 10, and then the light-emitting element 30 is repositioned in the second area 22 to form a disconnection configuration between the second area 22 and the first area 21.

As shown in the electrode pad in the middle of FIG. 10, the electrode pad on which the light-emitting element 30 is disposed in the second area 22 does not have the first area. When repairing the display panel, the first metal 201 is heated to a liquid state and the defective light-emitting element in the first area is removed. In this process, the first metal and the second metal in the first area are also removed together with the defective light-emitting element. Then, the light-emitting element 30 is repositioned in the second area 22 to form a configuration without the first area.

As shown in the electrode pad on the right side in FIG. 10, the electrode pad on which the light-emitting element 30 is disposed in the second area 22 does not have a third area. When repairing the display panel, the first metal 201 is heated to a liquid state, and the defective light-emitting element in the first area 21 is removed. In this process, entire first metal 201 in the third area together with the defective light-emitting element are removed, and then the light-emitting element 30 is repositioned in the second area 22 to form a configuration without a third area.

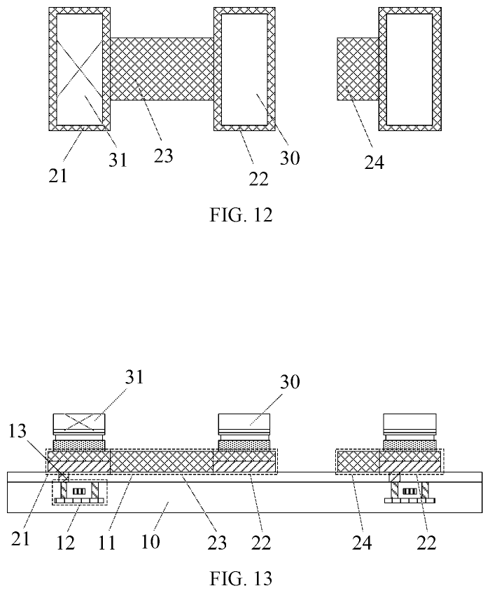

FIG. 11 is another schematic plan view of the display panel according to embodiments of the present disclosure. FIG. 12 is a schematic plan view of the electrode pad in FIG. 11 after repairing. At least one group of electrode pads includes an independent first area 21 and a shared second area 22. For example, two electrode pads form a group, and a light-emitting element 30 is provided on the first area 21 of each electrode pad in the group, and also includes two fourth areas 24. A fourth area 24 connects to the first area 21 and extends towards the second area 22. Neither of the two light-emitting elements 30 in FIG. 11 is defective, so the fourth area 24 is not connected to the second area 22, and the second area 22 has no light-emitting element.

FIG. 12 is a schematic plan view of an electrode pad after repairing, in which one electrode pad also includes a third area 23. The first area 21 of the electrode pad is connected to the second area 22 through the third area 23. A light-emitting element 30 is provided in the second area 22. The light-emitting element on the left is a defective light-emitting element 31. The repairing method is to repositioned the light-emitting element 30 in the second area 22 (it is not necessary to remove the defective light-emitting element 31 in the first area 21), and add a small amount of metal to electrically connect the first area 21 on the left to the second area 22 through melting. It is equivalent to changing the fourth area 24 on the left into the third area 23 by adding a small amount of metal. The light-emitting element 30 is disposed on the first area 21 of another electrode pad in a group of electrode pads, and a fourth area 24 is also included. The fourth area 24 extends toward the second area 22, that is, on the right side of FIG. 12, the light-emitting element 30 has no defect, and has a same structure as the electrode pad and the light-emitting element 30 on the right side of FIG. 8, and retains an original structure of the fourth area 24.

FIG. 13 is another schematic cross-sectional view of the display panel according to embodiments of the present disclosure, that is, the schematic cross-sectional view of FIG. 12. The array substrate 13 also includes a driving component and at least one first insulating layer 11 located between the driving component and the electrode pad. The first insulating layer 11 has a first via hole 13, and the electrode pad electrically connects with the driving component through the first via hole 13. The first area 21 of the electrode pad overlaps the first via hole 13. For the normal light-emitting element 30 on the right side of FIG. 12, a driving signal output by the thin film transistor 12 is transmitted to the light-emitting element 30 through the first via hole 13 and the first area 21 in sequence. For the repaired light-emitting element 30 on the left side of FIG. 12, the driving signal output by the thin film transistor 12 is transmitted to the light-emitting element 30 through the first via hole 13, the first area 21, the third area 23, and the second area 22 in sequence.

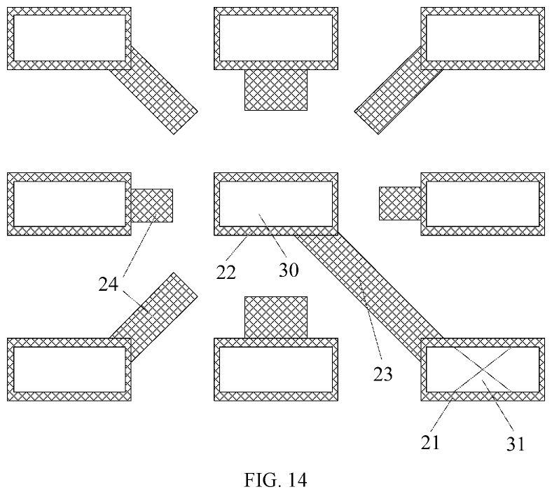

FIG. 14 is another schematic plan view of a display panel according to embodiments of the present disclosure. Similar to a structure of a group of electrode pads shown in FIG. 12, the difference in FIG. 14 is there are eight electrode pads in a group, and each electrode pad includes an independent first area 21 and a shared second area 22. The light-emitting element located on the lower right electrode pad is a defective light-emitting element 31. The electrode pad also includes a third area 23. The first area 21 of the electrode pad is connected to the second area 22 through the third area 23. The second area 22 is arranged with a repositioned light-emitting elements 30. The first area 21 of the remaining seven electrode pads in the group of electrode pads is provided with a light-emitting element 30 that do not suffer from a defect, and also includes a fourth area 24 extending toward the second area 22.

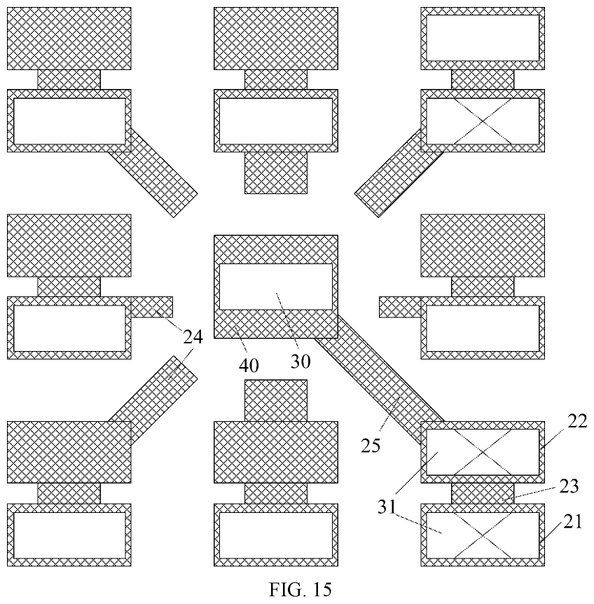

FIG. 15 is another schematic plan view of a display panel according to embodiments of the present disclosure. A backup electrode pad 40 is also configured on the array substrate 10. In addition to the first area 21, the second area 22, and the third area 23, at least part of the electrode pad also includes a fourth area 24. The fourth area 24 extends towards an adjacent backup electrode pad 40. The eight electrode pads in FIG. 15 share one backup electrode pad 40.

When a light-emitting element in the first area 21 of an electrode pad is a defective light-emitting element 31, such as the upper right electrode pad in FIG. 15, the light-emitting element 30 can be repositioned in the second area 22 of the electrode pad. The electrical connection between the first area 21 and the second area 22 is disconnected for repairing.

In some embodiments, the second area 22 of at least one electrode pad is connected to a backup electrode pad 40 through a connecting bridge 25, and the light emitting-element 30 is disposed on the backup electrode pad 40. When a defective light-emitting element 31 appears in the first area 21 of an electrode pad, and the repositioned light-emitting element of the second area 22 is also defective. For example, in the electrode pad on the lower right of FIG. 15, the light-emitting element 30 can be repositioned on the backup electrode pad 40, and a small amount of metal is added. By melting and connecting, the second area 22 of the electrode pad is electrically connect with the backup electrode pad 40 which is equivalent to adding a small amount of metal to convert the fourth area 24 of the electrode pad to the connecting bridge 25. By arranging a shared backup electrode pad 40, when a defective light-emitting element appears in both the first area 21 and the second area 22 of a certain electrode pad, the backup electrode pad 40 can be used for repairing, which improves a fault tolerance rate of a display panel manufacturing process, achieving “double insurance”.

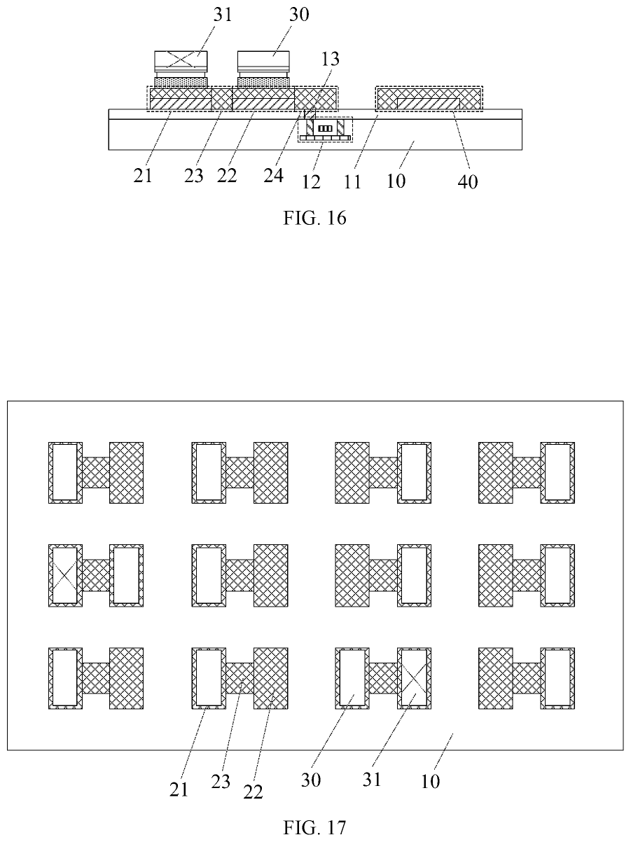

FIG. 16 is another schematic cross-sectional view of the display panel according to embodiments of the present disclosure, that is, a localized schematic cross-sectional view of FIG. 15. The array substrate 10 also includes a driving component and at least a first insulating layer 11 located between the driving component and the electrode pad. The first insulating layer 11 has a first via hole 13, and the electrode pad is electrically connected to the driving component through the first via hole 13. The fourth area 24 of the electrode pad overlaps with the first via hole 13. When repairing the display panel, it is necessary to irradiate ultraviolet light from the lower surface of the array substrate 10 to the first area 21, the second area 22, and the third area 23 to heat the electrode pad. Thus, the overlapping structure of the first via hole 13 and the fourth area 24 can prevent ultraviolet light from damaging a structure and performance of the thin film transistor 12, as well as prevent the thin film transistor 12 from blocking ultraviolet light.

FIG. 17 is another schematic plan view of a display panel according to embodiments of the present disclosure. The first area 21, the third area 23, and the second area 22 are arranged in sequence along a first direction, and the first direction is a direction in which an edge of the display panel pointing to a center of the display panel. Taking the display panel shown in FIG. 17 as an example, when a defective light-emitting element 31 appears in the first area 21 on the left side of the display panel, the repositioned light-emitting element 30 in the second area 22 is located on the right side of the defective light-emitting element 31. When a defective light-emitting element 31 appears in the first area 21 on the right side of the display panel, the repositioned light-emitting element 30 in the second area 22 is located on the left side of the defective light-emitting element 31. This means the repositioned light-emitting element 30 is closer to a center of the display panel than the defective light-emitting elements 31. This can make the overall image presented by the display panel more compact and minimize an impact of the defective light-emitting element and correspondingly remedy the impact on a display effect.

Embodiments of the present disclosure also provides a display device, which may be a display device such as a mobile phone, a watch, or a tablet computer, including the display panel provided in any of the above embodiments.

The display device provided by embodiments of the present disclosure has same technical features as the display panel provided by the above embodiments. Therefore, the display device can also address same technical issues and achieve same technical effects.

Compared to the existing technical approaches, the present disclosure provides an array substrate and a plurality of electrode pads formed over the array substrate. At least one electrode pad of the plurality of electrode pads includes a first area, a second area, and a third area. The third area connects to each of the first area and the second area. A light-emitting element is configured over the first area of the at least one electrode pad of the plurality of electrode pads. A width of the third area is less than each of a width of the first area and a width of the second area; and/or a melting point of the third area is lower than a melting point of the first area or a melting point of the second area, which is convenient to disconnect an electrical connection between the first area and the second area. If the light-emitting element provided over a first area fails, the electrical connection between the first area and the second area can be disconnected, and the light-emitting element can be repositioned in the second area to repair the display panel without the need for arranging an additional backup electrode, saving a lot of space, which is conducive to an integration of other functional structures and solving the technical issue of low efficiency of space utilization of the display panel.

It should be noted that in the present disclosure, relational terms such as “first” and “second” are only used to distinguish one entity or one operation from another entity or another operation, and do not necessarily require or imply there is such actual relationship or sequence between entities or operations. Furthermore, the terms “comprises,” “includes,” or any other variations thereof are intended to cover a non-exclusive inclusion such that a process, method, article, or apparatus that includes a list of elements includes not only those elements, but also those not expressly listed other elements, or elements inherent to the process, method, article or equipment. Without further limitation, an element defined by the statement “comprises a . . . ” does not exclude the presence of additional identical elements in a process, method, article, or apparatus that includes the stated element.

The above descriptions are only specific embodiments of the present disclosure, enabling those persons of ordinary skill in the art to understand or implement the present disclosure. Various modifications to embodiments of the present disclosure will be readily apparent to persons of ordinary skill in the art, and the generic principles defined herein may be practiced in other embodiments without departing from the spirit or scope of the disclosure. Therefore, the present disclosure is not to be limited to embodiments described here but is to be accorded the widest scope consistent with the principles and novel features disclosed here.

What is claimed is:

1. A display panel, comprising
an array substrate and a plurality of electrode pads formed over the array substrate, wherein
at least one electrode pad of the plurality of electrode pads comprises a first area, a second area, and a third area; the third area connects to at least one of the first area and the second area; a light-emitting element is configured over the first area of the at least one electrode pad of the plurality of electrode pads; and
a width of the third area is less than at least one of a width of the first area and a width of the second area; and/or a melting point of the third area is lower than a melting point of the first area or a melting point of the second area.

2. The display panel of claim 1, wherein the light-emitting element is positioned over the second area of the at least one electrode pad of the plurality of electrode pads.

3. The display panel of claim 2, wherein the second area of one electrode pad of the plurality of electrode pads having the light-emitting element
is disconnected from the first area; or
does not have the first area; or
does not have the third area.

4. The display panel of claim 1, wherein along a direction from the first area to the second area, the width of the third area decreases first and then increases.

5. The display panel of claim 4, wherein an edge of the third area is concave arc-shaped or concave polyline-shaped.

6. The display panel of claim 1, wherein
the third area comprises a first metal;
the first area and/or the second area comprise a second metal; and
a melting point of the first metal is lower than a melting point of the second metal.

7. The display panel of claim 6, wherein a melting point of the first metal is below 300° C., and a melting point of the second metal is above 500° C.

8. The display panel of claim 6, wherein
the at least one of the first area and the second area comprises n layers of metal;
the third area comprises m layers of metal; and
m <n.

9. The display panel of claim 1, wherein a spacer layer is positioned between the third area and the array substrate.

10. The display panel of claim 9, wherein along a direction from the first area to the second area, a thickness of the spacer layer increases first and then decreases.

11. The display panel of claim 1, wherein
the array substrate further comprises a driving component and at least one first insulating layer located between the driving component and an electrode pad of the plurality of electrode pads, a first via hole is arranged in a first insulating layer of the at least one first insulating layer, and the electrode pad is electrically connected to the driving component through the first via hole; and
the second area of the electrode pad overlaps with the first via hole.

12. The display panel of claim 1, wherein
at least one group of electrode pads comprises first areas that are independently arranged and a shared second area;
an electrode pad of the at least one group of electrode pads further comprises a third area, the first area of the electrode pad connects to the second area through the third area, and the light-emitting element is positioned over the second area; and
the first area of remaining electrode pads of the at least one group of electrode pads is configured with the light-emitting element and comprises a fourth area, and the fourth area extends towards the second area.

13. The display panel of claim 12, wherein
the array substrate further comprises a driving component and at least one first insulating layer that is located between the driving component and the electrode pad, a first via hole is configured in a first insulating layer of the at least one first insulating layer, and the electrode pad is electrically connected to the driving component through the first via hole; and
the first area of the electrode pad overlaps with the first via hole.

14. The display panel of claim 1, wherein
the array substrate further comprises one or more backup electrode pads; and
at least a portion of an electrode pad of the plurality of electrode pads comprises a fourth area, the fourth area extends towards an adjacent backup electrode pad.

15. The display panel of claim 14, wherein
the array substrate further comprises a driving component and at least one first insulating layer located between the driving component and the electrode pad, a first via hole is configured in a first insulating layer of the at least one first insulating layer, and the electrode pad is electrically connected to the driving component through the first via hole; and
the fourth area of the electrode pad overlaps with the first via hole.

16. The display panel of claim 14, wherein the second area of at least one electrode pad of the plurality of electrode pads is connected to the backup electrode pad via a connecting bridge, and the light-emitting element is positioned over the backup electrode pad.

17. The display panel of claim 1, wherein
the first area, the third area, and the second area are arranged sequentially along a first direction; and
the first direction is from an edge of the display panel towards a center of the display panel.

18. The display panel of claim 1, wherein
the array substrate further comprises a thin film transistor; and
the third area does not overlap with the thin film transistor.

19. The display panel of claim 1, wherein the light-emitting element is a vertical structured Micro-LED.

20. A display device, comprising:
a display panel comprising:
an array substrate and a plurality of electrode pads formed over the array substrate, wherein
at least one electrode pad of the plurality of electrode pads comprises a first area, a second area, and a third area; the third area connects to at least one of the first area and the second area; a light-emitting element is configured over the first area of the at least one electrode pad of the plurality of electrode pads; and
a width of the third area is less than at least one of a width of the first area and a width of the second area; and/or a melting point of the third area is lower than a melting point of the first area or a melting point of the second area.
